(19) United States
(12) Patent Application Publication
(10) Pub. No.: US 2023/0069518 A1
(43) Pub. Date: Mar. 2, 2023

(54) SEMICONDUCTOR DEVICE, AND MANUFACTURING METHOD FOR SAME

(71) Applicant: UltraMemory Inc., Tokyo (JP)

(72) Inventor: Masatoshi HASEGAWA, Tokyo (JP)

(21) Appl. No.: 17/919,154

(22) PCT Filed: May 11, 2020
(86) PCT No.: PCT/JP2020/018827

§ 371 Date: Oct. 14, 2022

(51) Int. Cl. H01L 25/065; H01L 25/07; H01L 25/10; H01L 23/66; H01L 23/538

(52) U.S. Cl. CPC H01L 25/0657; H01L 25/07; H01L 25/105; H01L 23/66; H01L 23/538

(57) ABSTRACT

A semiconductor device has laminated therein three or more chips. The plurality of chips are provided with substrates, transmission coils, and reception coils that are disposed in regions where the transmission coils and the reception coils do not overlap with each other in an in-plane direction of the substrates. The transmission coils are disposed in regions that are in a lamination direction and that are adjacent to and overlap with reception coils of other chips. The reception coils are configured to allow data transmission with respect to the transmission coils that are disposed on the same substrates.

### TECHNICAL FIELD

The present invention relates to a sem±conductor device and a method for manufacturing the semiconductor device.

### BACKGROUND ART

Typically, volatile memory (RAM) such as dynamic random access memory (DRAM) has been known as a storage device. For the DRAM, there has been a demand for a high capacity for enhanced performance and a great data amount of an arithmetic device (hereinafter referred to as a logic chip). For this reason, such a high capacity has been achieved by memory (a memory cell array, a memory chip) miniaturization and two-dimensional additional cell installation Meanwhile, the high capacity of this type has reached the limit thereof due to vulnerability to noise due to miniaturization, a die area increase, etc.

For these reasons, a technique of achieving the high capacity in such a manner that a plurality of planar memories is stacked three-dimensionally (three-dimensionalization) has been recently developed. For example, a semiconductor device using coils for communication among stacked memories has been proposed. (see, e.g., Patent Documents 1 and 2).

Patent Document 1: Japanese Unexamined Patent Application, Publication No. 2009-295699

Patent Document 2: Japanese Unexamined Patent Application, Publication No. 2012-209769

### DISCLOSURE OF THE INVENTION

### Problems to be Solved by the Invention

In Patent Document 1, three coils are used to form one communication channel. A coil function is set for each stacked layer so that bidirectional communication can be made. One of three coils is not constantly used.

In Patent Document 2, chips are stacked on each other, each chip including two pairs of transmission and reception coils formed concentrically. Patent Document 2 further discloses a transmitter and a receiver each connected to the coils in pair. A connection path between the transmitter and the receiver is changed between two pairs of coils so that bidirectional communication can be made. The outer coil needs to have a greater diameter in order to concentrically arrange two coils. Thus, in Patent Documents 1 and 2, the area of arrangement of the coil is large. Thus, the area of arrangement of the coil needs to be suitably reduced.

The present invention is intended to provide a semiconductor device and a method for manufacturing the semiconductor device so that the area of arrangement of the coil can be reduced.

### Means for Solving the Problems

The present invention relates to a semiconductor device including three or more chips stacked on each other. Each of the chips includes a substrate, a transmission coil, and a reception coil provided in a region where the reception coil does not overlap with the transmission coil in an in-plane direction of the substrate. The transmission coil is arranged in a region where the transmission coil is adjacent to and. overlaps with the reception coil of another chip in a stacking direction The reception coil is configured such that data is transmittable between the reception coil and the transmission

Two or more pairs of the reception coil and the transmission coil are preferably provided.

The transmission coil is preferably provided at a predetermined position on the substrate at a position opposing the reception coil with respect to a reference axis extending along the in-plane direction.

The substrate preferably includes a front surface as one surface in a thickness direction, and a back surface as the other surface in the thickness direction The front surface is preferably stacked adjacent to the front surface of the substrate of another chip, and the back surface is preferably stacked adjacent to the back surface of the substrate of still another chip.

The transmission coil is preferably, on the substrate, provided at a predetermined position opposing the reception coil with respect to an intersecton between two reference axes extending in the in-plane direction and extending perpendicular to each other.

The substrate preferably includes the front surface as one surface in the thickness direction, and the back surface as the other surface in the thickness direction. The front surface is preferably stacked adjacent to the back surface of the substrate of another chip, and the back surface is preferably stacked adjacent to the front surface of the substrate of still another chip.

The transmission coil is preferably, in the stacking direction, adjacent to the reception coil of another chip with at least one still another chip interposed therebetween.

The chip preferably includes a transmission circuit connected to the transmission coil to transmit transmission data to the transmission coil, a reception circuit connected to the reception coil to receive reception data from the reception coil, a transmission-side driver that switches connection between the transmission coil and the transmission circuit, and a reception-side receiver that switches connection between the reception coil and the reception circuit.

The transmission-side driver preferably switches the connection between the transmission coil and the transmission circuit based on a transmission direction of the transmission data along the stacking direction, and the reception-side receiver preferably switches the connection between the reception coil and the reception circuit according to switching by the transmission-side driver.

The transmission coil is preferably different from the reception coil in at least anyone of the number of turns, a wire width, an inter-wire space, or a wire to be used.

The present invention relates to a method for manufacturing the above-described semiconductor device, the semiconductor device being manufactured in such a manner that wafers are stacked on each other and are subsequently divided into pieces.

### Effects of the Invention

According to the present invention, the semiconductor device and the method for manufacturing the semiconductor device are provided so that the area of arrangement of the coil can be reduced.

### BRIEF DESCRIPTION OF THE DRAWINGS

FIG. 1 is a conceptual diagram showing bonded chips of a semiconductor device according to a first embodiment of the present invention;

FIG. 2 is a plan view showing a positional relationship among coils in the chips of the semiconductor device of the first embodiment;

FIG. 3 is a sectional view showing the semiconductor device of the first embodiment;

FIG. 4 is a schematic chart showing the flow of data transmission in the semiconductor device of the first embodiment;

FIG. 5 is a plan view showing a positional relationship among coils in chips of a semiconductor device of a second embodiment of the present invention;

FIG. 6 is a sectional view showing the semiconductor device of the second embodiment;

FIG. 7 is a schematic chart showing the flow of data transmission in the semiconductor device of the second embodiment;

FIG. 8 is a plan view showing a positional relationship among coils in chips of a semiconductor device of a third embodiment of the present invention; and

FIG. 9 is a sectional view showing the semiconductor device of the third embodiment.

### PREFERRED MODE FOR CARRYING OUT THE INVENTION

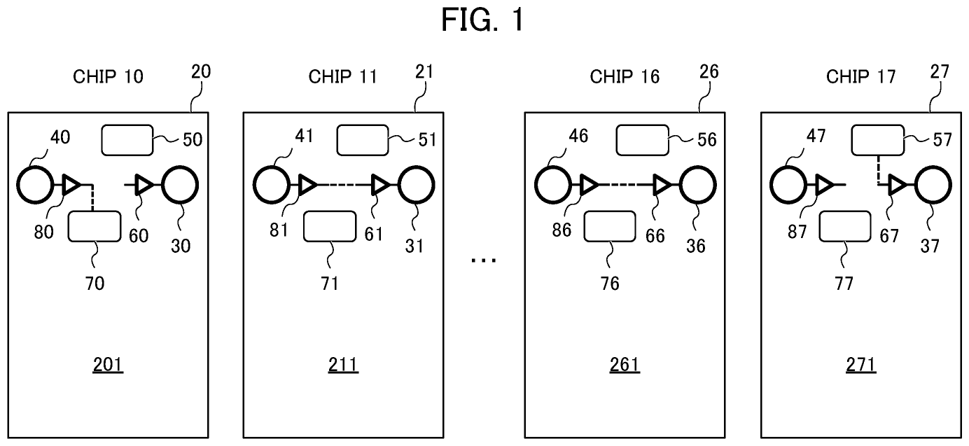

Hereinafter, a semiconductor device 1 and a method for manufacturing the semiconductor device 1 according to each embodiment of the present invention will be described with reference to FIGS. 1 to 9. First, the outline of the semiconductor device 1 according to each embodiment will be described. The semiconductor device 1 is, for example, a DRAM. The semiconductor device 1 is configured such that a plurality of chips 10, 11, 12, is stacked on each other. The semiconductor device 1 performs communication among the chips 10, 11, 12, . . . by means of coils. The semiconductor device 1 according to each embodiment below is configured for reducing the area of arrangement of the communication coil.

### [First Embodiment]

Next, a semiconductor device 1 and a method for manufacturing the semiconductor device 1 according to a first embodiment of the present invention will be described with reference to FIGS. 1 to 4. The semiconductor device 1 according to the present embodiment is configured such that three or more chips 10, 11, 12, . . . are stacked on each other. In the present embodiment, an example where the semiconductor device 1 is configured such that eight chips 10, 11, 12, 17 are stacked on each other will be described. Specifically, the semiconductor device I is configured such that the eight rectangular plate-shaped chips 10, 11, 12, . . . are stacked on each other. The semiconductor device 1 is manufactured in such a manner that wafers are stacked on each other and are subsequently divided into pieces.

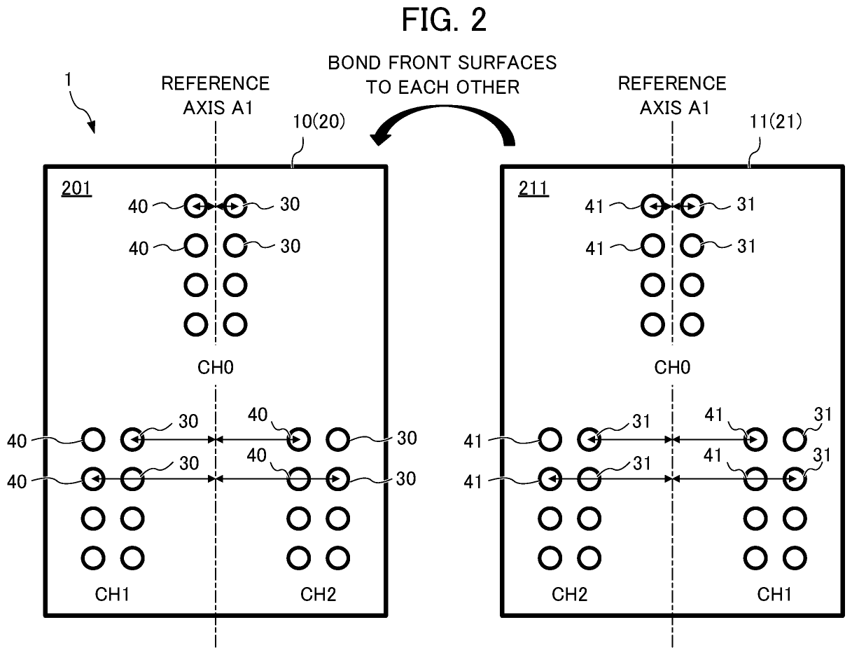

The chips 10, 11, 12, . . . are so-called memory chips. As shown in FIGS. 1 and 2, the chip 10, 11, 12, . . . includes a substrate 20, 21, 22, . . . , transmission coils 30, 31, reception coils 40, 41, . . . , a transmission circuit 50, 51, . . . , a transmission-side driver 60, 61, . . . , a reception circuit 70, 71, . . . , and a reception-side receiver 80, 81,

Note that for the sake of simplicity in description, the chip 10 will be described as an example when it is not necessary to distinguish the chips from each other.

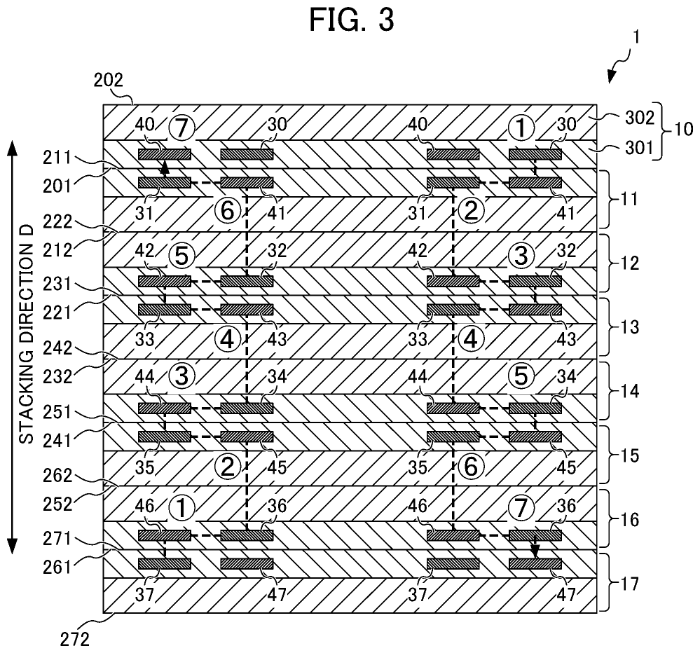

The substrate 20 is formed, for example, using a wiring layer 301 and a Si substrate portion 302 adjacent to the wiring layer 301 in a thickness direction thereof, as shown in FIG. 3. The substrate 20 is, for example, formed in a rectangular plate shape. For the substrate 20, a side on which the wiring layer 301 is exposed in the thickness direction will be described as a front surface 201, and a side on which the Si substrate portion 302 is exposed in the thickness direction will be described as a back surface 202. That is, the substrate 20 includes the front surface 201 as one surface in the thickness direction and the back surface 202 as the other surface in the thickness direction In the present embodiment, the substrates 20, 21, . . . in the plurality' of chips 10, 11, 12, . . . stacked on each other are configured such that front surface 201, 211, . . . sides are bonded to each. other and back surface 202, 212, . . . sides are bonded to each other along a stacking direction D, as shown in FIGS. 1 and. 3. For example, the chip 11 is stacked such that a front surface 211 thereof is adjacent to the front surface 201 of the substrate 20 of another chip 10. Moreover, the chip 11 is stacked such that a back surface 212 thereof is adjacent to a back surface 222 of the substrate 22 of still another chip 12.

The transmission coils 30 are arranged in The wiring layer 301. The transmission coils 30 are arranged such that an axial direction thereof faces the stacking direction D (the thickness direction) of the substrate 20. In the present embodiment, the transmission coils 30 are arranged separately for three channels (CH1, CH2, CH3) and four transmission coils 30 are arranged for each channel, as shown in FIG. 2. The transmission coil 30 is different from the reception coil 40 in at least any one of the number of turns, a wire width, an inter-wire space, or a wire to be used.

The reception coils 40 are arranged in the wiring layer 301. The reception coils 40 are arranged such that an axial direction thereof faces the thickness direction of the substrate 20. That is, the reception coils 40 and the transmission coils 30 are arranged such that the axial directions thereof are aligned with each other. The reception coil 40 is provided in a region where the reception coil 40 does not overlap with the transmission coil 30 in an in-plane direction of the substrate 20. Moreover, the reception coil 40 is configured such that data is transmittable between the reception coil 40 and the transmission coil 30 arranged on the same substrate 20. In The present embodiment, the reception coil 40 is electrically connected to the transmission coil 30, and such connection is switchable. In The present embodiment, two or more pairs of the reception coil 40 and the transmission coil 30 are provided. Specifically, four pairs of the reception coil 40 and the transmission coil 30 are provided for each channel, as shown in FIG. 2.

According to the transmission coil 30 and the reception coil 40 as described above, the transmission coil 30 is, as shown in FIG. 2, arranged at a predetermined position on the substrate 20 at a position opposing the reception coil 40 with respect to a reference axis Al extending along the in-plane direction Specifically, the transmission coil 30 is arranged at a position line-symmetrical to the reception coil 40 paired therewith. Moreover, the transmission coil 30 is arranged in a region where the transmission coil 30 is adjacent to the reception coil 41 of another chip 11 in the stacking direction D and overlaps with the reception coil 41 in the stacking direction D. That is, the reception coil 40 is arranged in a region where the reception coil 40 is adjacent to the transmission coil 31 of another chip 11 in the stacking direction D and overlaps with the transmission coil 31 in the stacking direction D. With this configuration, the transmission coil 30 is configured such that data is transmittable to the reception coil 41 of another chip 11. The reception coil 40 is configured such that data is receivable from the transmission coil 31 of another chip 11.

The transmission circuit 50 is a circuit capable of transmitting transmission data to the transmission coils 30. The transmission circuit 50 is connected to the transmission coils 30. Specifically, the transmission circuit 50 is configured such that connection to the transmission coils 30 is switchable.

The transmission-side driver 60 is a driver including a switching element on an input side, for example. The transmission-side driver 60 switches connection among the transmission coils 30 and the transmission circuit 50. That is, the transmission-side driver 60 switches connection among the transmission circuit 50 and the transmission coils 30 and connection among the transmission coils 30 and the reception coils 40.

The reception circuit 70 is a circuit capable of receiving reception data from the reception coils 40. The reception circuit 70 is connected to the reception coils 40.

The reception-side receiver 80 is a receiver including a switching element on an output side, for example. The reception-side receiver 80 switches connection among the reception coils 40 and the reception circuit 70. The reception-side receiver 80 switches connection among the reception circuit 70 and the reception coils 40 and connection among the transmission coils 30 and the reception coils 40.

According to the semiconductor device I described above, the semiconductor device 1 is configured such that the transmission coils 30, 31, . . . and the reception coils 40, 41, . . . are alternatively arranged and stacked on each other in the stacking direction D, as shown in FIG. 3. Moreover, in the Present embodiment, the semiconductor device I has a channel for transmitting data in one direction in the stacking direction D and a channel for transmitting data in the other direction in the stacking direction D.

The transmission-side driver 60, 61, . . . switches connection among the transmission coils 30, 31, . . . and the transmission circuit 50, 51, . . . based on a transmission direction of the transmission data along the stacking direction D. The reception-side receiver 60, 81, . . . switches connection among the reception coils 40, 41, e and the reception circuit 70, 71, . . . according to switching by the transmission-side driver 60, 61. For example, in the channel for transmitting data in one direction in the stacking direction D, the transmission-side driver 67 connects the transmission circuit 57 and the transmission coils 37 to each other in the chip 17 from which data transmission starts. In the present embodiment, the transmission-side driver 67 in one channel (the channel for transmitting data in one direction in the stacking direction D) in the chip 17 connects the transmission circuit 57 and the transmission coils 37 to each other. On the other hand, in the chip 10 in which data transmission ends (data is stored), the reception-side receiver 80 connects the reception circuit 70 and the reception coils 40 to each other. In other chips 11, . . . , 16, the transmission-side 61, . . . , 66 and the reception-side receivers 81, . . . , 86 connect the transmission coils 31, . . . , 36, and the reception coils 41, . . . , 46. With this configuration, the chip 17 operates as a transmission unit that transmits data, as shown in FIG. 3. The chips 11 to 16 operate as repeat units that transfer data The chip 10 operates as a reception unit that receives data

In the present embodiment, in another channel (the channel for transmitting data in the other direction in the stacking direction D) in the chip 10, the transmission-side driver 60 connects the transmission circuit 50 to the transmission coils 30 to each other. In the same channel in the chip 17, the reception-side receiver 87 connects the reception circuit 77 and the reception coils 47 to each other. In other chips 11, . . . , 16, the transmission-side drivers 61, . . . , 66 and the reception-side receivers 61, . . . , 86 connect the transmission coils 31, . . . , 36, and the reception coils 41, . . . , 46.

Next, the flow of data transmission will be described. In data transmission in one direction in the stacking direction D, data transmitted from the transmission circuit 57 of the chip 17 is, as shown in FIG. 3, transmitted from the transmission coil 37 of the chip 17 to the reception coil 46 of the chip 16. Next, the data received by the chip 16 is transmitted from the reception coil 46 of the chip 16 to the transmission coil 36 of the chip 16. The transmission coil 36 of the chip 16 transmits the data to the reception coil 45 of the chip 15. The data received by the chip 15 is transmitted from the reception coil 45 of the, chip 15 to the transmission coil 35 of the chip 15. This process is repeated until the chip 11. In the chip 10, the reception coil 40 receives the data transmitted from the transmission coil 31 of the chip 11. The data received by the reception coil 40 of the chip 10 is transmitted to the reception circuit 70 of the chip 10.

In data transmission in the other direction in the stacking direction D, data transmitted from the transmission circuit 50 of the chip 10 is, as shown in FIG. 3, transmitted. from the transmission coil 30 of The chip 10 to the reception coil -11 of the chip 11. Next, the data received by the chip 11 is transmitted from the reception coil 41 of the chip 11 to the transmission coil 31 of the chip 11. The transmission coil 31 of the chip 11 transmits the data to the reception coil 42 of the chip 12. The data received by the chip 12 is transmitted from the reception coil 42 of the chip 12 to the transmission coil 32 of the chip 12. This process is repeated until the chip 16. In The chip 17, the reception coil 47 of the chip 17 receives the data transmitted from the transmission coil 36 of the chip 16. The data received by the reception coil 47 of the chip 17 is transmitted to the reception circuit 77 of the chip 17.

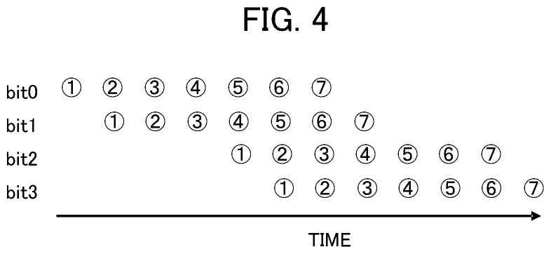

Next, data transmission timing will be described with reference to FIG. 4. As shown in FIG. 4, in one channel, data with a bit number of 0 (referred to as bit0) is transmitted in the order of a path 1 to a path 7 of FIG. 4 over time. Next, data with a bit number of1 (referred to as bit1) is transmitted in the path. 1 upon transmission of the bit0 in the path 2. Next, data with a bit number of 2 (referred to as bit2) is transmitted in the path I upon transmission of the bit0 in the path 5 and transmission of the bit1 in the path 4. Next, data with a bit number of 3 (referred to as bit3) is transmitted in the path i upon transmission of the bit0 in the path 7, transmission of the vita in the path 6, and transmission of the bit2 in the path 2. That is, data transmission is performed such that operation is not simultaneously performed. In the paths adjacent to each other in the stacking direction D. That is, control is made such that when the reception coil 46 of the chip 16 receives data from the transmission coil 37 of the chip 17, the reception coil 44 of the chip 14 receives no data from the transmission coil 35 of the chip 15, for example. With this configuration, the reception coil 46 and the reception coil 44 adjacent to each other through the transmission coil 35 in the stacking direction D do not operate simultaneously. Thus, favorable communication can be achieved without occurrence of crosstalk noise.

According to the semiconductor device 1 and The method for manufacturing the semiconductor device 1 according to the first embodiment as described above, the following advantageous effects are produced.

(1) The semiconductor device 1 includes three or more chips 10, 11, 12, . . . stacked on each other. Each of the chips 10, 11, 12, . . . includes the substrate 20, 21, . . . , the transmission coils 30, 31, , and the reception coils 40, 41, . . . provided in the region where the reception coils 40, 41, . . . do not overlap with the transmission coils 30, 31, in the in-plane direction of the substrate 20, 21, . . . The transmission coil 30, 31, . . . is arranged in the region where the transmission coil 30, 31, . . . is adjacent to and overlaps with the reception coil 40, 41, . . . of another chip 10, 11, 12, . . . in the stacking direction D. The reception coil 40, 41, is configured such that data is transmittable between the reception coil 40, 41, . . . and the transmission coil 30, 31, arranged on the same substrate 20, 21, . . . With this configuration, data communication among the chips 10, 11, 12, . . . stacked on each other can be achieved using two types of coils without any diameter limitation. Thus, the area of arrangement of the coil can be reduced.

(2) Two or more pairs of the reception coil 40, 41, and the transmission coil 30, 31, . . . are provided. With this configuration, a plurality of coils with a small arrangement area is arranged so that a plurality of channels can be provided.

(3) The transmission coil 30, 31, is provided at the predetermined position on the substrate at the position opposing the reception coil 40, 41, . . . with respect to the reference axis Al extending along the in-plane direction With this configuration, the plurality of chips 10, 11, 12, can be properly stacked considering only bonding of the chips 10,

Thus, the semiconductor device 1 can be more easily manufactured.

(4) The substrate 20, 21, . . . includes the front surface 201 as one surface in the thickness direction, and the back surface 202 as the other surface in the thickness direction The front surface 201 is stacked adjacent to the front surface 201 of the substrate of another chip 10, 11, 12, . . . , and the back surface 202 is stacked adjacent to the back surface 202 of the substrate 20, 21, . . . of still another chip 10, 11, 12. With this configuration, proper communication among the chips 10, 11, 12, . . . can be achieved.

(5) The chip 10, 11, 12, . . . includes the transmission circuit 50, 51, . . . connected to the transmission coils 30, 31, . . . to transmit the transmission data to the transmission coils 30, 31, . . . , the reception circuit 70, 71, . . . connected to the reception coils 40, 41, to receive the reception data from the reception coils 40, 41, . . . , the transmission-side driver 60, 61, . . . chat switches connection among the transmission coils 30, 31, and the transmission circuit 50, 51, . . . , and the reception-side receiver 80, 81, that switches connection among the reception coils 40, 41, and the reception circuit 70, 71, . . . With this configuration, data transmission and data reception are allowed in any of the chips 10, 11, 12, . . . , and device flexibility can be improved.

(6) The transmission-side driver 60, 61, . . . switches connection among the transmission coils 30, 31, . . . and the transmission circuit 50, 51, . . . based on the transmission direction of the transmission data along the stacking direction D, and the reception-side receiver 80, 81, . . . switches connection among the reception coils 40, 41, . . . and the reception circuit 70, 71, . . . according to switching by the transmission-side driver 60, 61, . . . With this configuration, the transmission circuit 50, 51, . . . and the receiving circuit 70, 71, . . . are communicably connected to each other. Thus, the transmission path can be flexibly formed.

m The transmission coil 30, 31, . . . is different from the reception coil 40, 41, in at least any one of the number of turns, a wire width, an inter-wire space, or a wire to be used. With this configuration, the accuracy of data transmission can be optimized.

(8) in the method for manufacturing the above-described semiconductor device 1, the semiconductor device 1 is manufactured in such a manner that the wafers are stacked on each other and are subsequently divided into pieces. With this configuration, the plurality of chips 10, 11, 12, . . . can be easily manufactured in mass quantities.

### [Second Embodiment]

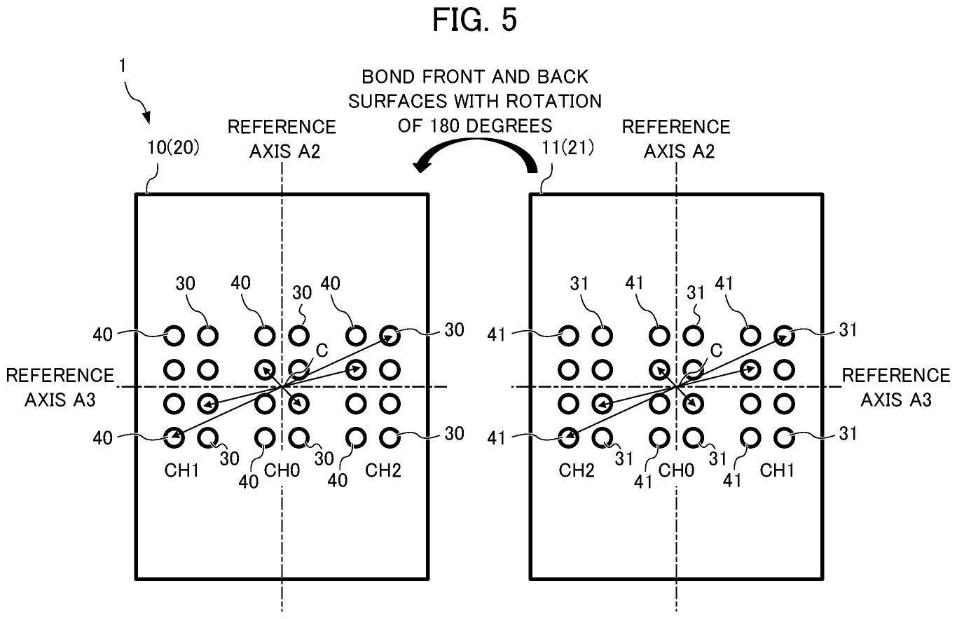

Next, a semiconductor device 1 and a method for manufacturing the semiconductor device 1 according to a second embodiment of the present invention will be described with reference to FIGS. 5 to 7. In description of the second embodiment, the same reference numerals are used to represent the same elements as those of the above-described embodiment, and description thereof will be omitted or simplified. The semiconductor device 1 according to the second embodiment is different from that of the first embodiment in that a transmission coil. 30 is, on a substrate 20, provided a predetermined position opposing a reception coil 40 with respect to an intersection C between two reference axes A2, A3 extending in an in-plane direction and extending perpendicular to each other. Thus, the semiconductor device 1 according to the second embodiment is different from that of the first embodiment in that a substrate 21 is stacked such that a front surface 211 thereof is adjacent to a back surface 202 of a substrate 20 of another chip 10. Moreover, the semiconductor device 1 according to the second embodiment is different from that of the first embodiment in that a back surface 212 is stacked adjacent to a front surface 221 of a substrate 22 of still another chip 12. The semiconductor device 1 according to the second embodiment is different from that of the first embodiment in that the transmission coil 30 and the reception coil 40 are line-symmetrical to each other with respect to one reference axis A2, but are not line-symmetrical to each other with respect to another reference axis A3.

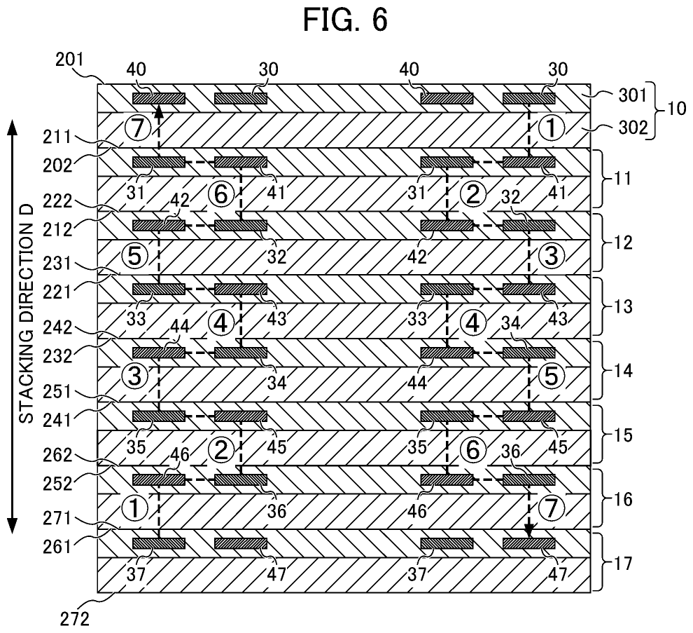

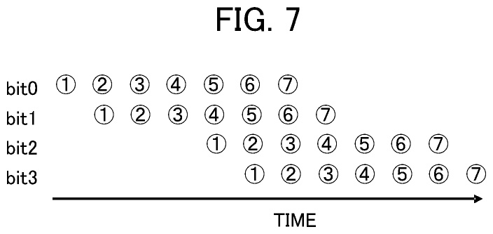

According to the semiconductor device 1 as described above, one chip 11 is stacked on another chip 10 adjacent to the chip 11 in a stacking direction C with the chip 11 rotated. 180 degrees about the intersection C, as shown in 5. With this configuration, the back surface 212 of one chip 11 is bonded to the front surface 221 of another chip 12, as shown in FIG. 6. As shown in FIG. 7, data transmission timing is similar to that of the first embodiment That is, operation is not performed simultaneously in paths adjacent to each other in the stacking direction D.

According to the semiconductor device 1 and the method for manufacturing the semiconductor device 1 according to the second embodiment as described above, the following advantageous effects are produced.
(9) The transmission coil 30 is, on the substrate 20, provided at the predetermined position opposing the reception coil 40 with respect to the intersection between two reference axes A2, A3 extending in the in-plane direction and extending perpendicular to each other. With this configuration, the plurality of chips 10, 11, 12, . . . can be properly stacked considering only bonding of the chips 10, 11, 12, . . . Thus, the semiconductor device i can be more easily manufactured.

(10) The substrate 21 includes the front surface 211 as one surface in the thickness direction, and the back surface 212 as the other surface in the thickness direction The front surface 211 is stacked adjacent to the back surface 202 of the substrate 20 of another chip 10, and the back surface 212 is stacked adjacent to the front surface 221 of the substrate 22 of still another chip 12. With this configuration, proper communication among the chips 10, 11, 12, . . . can be achieved.

### [Third Embodiment]

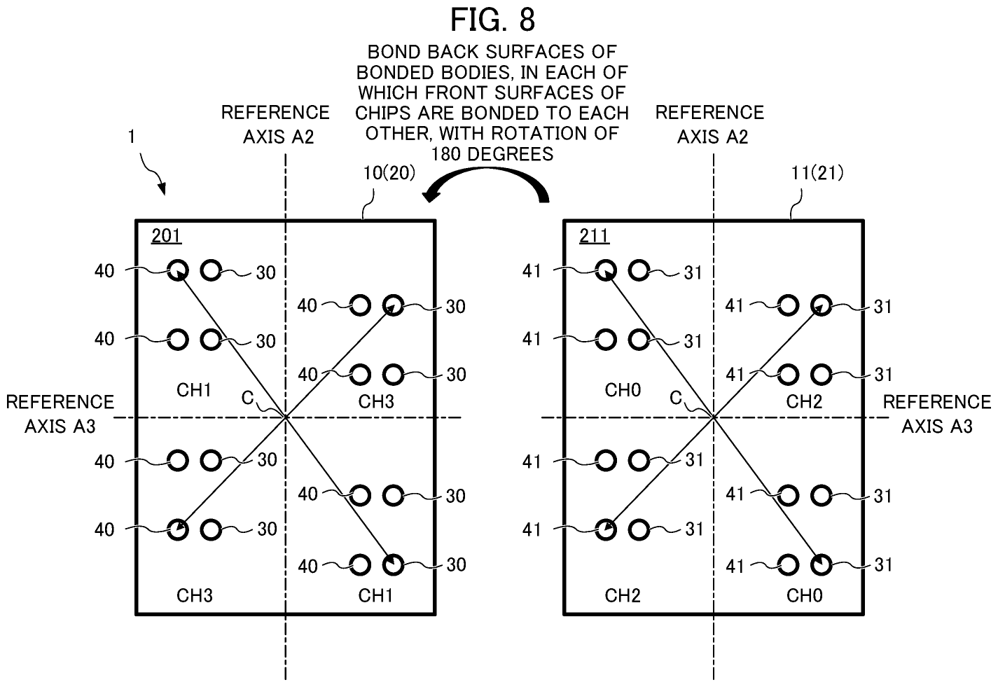

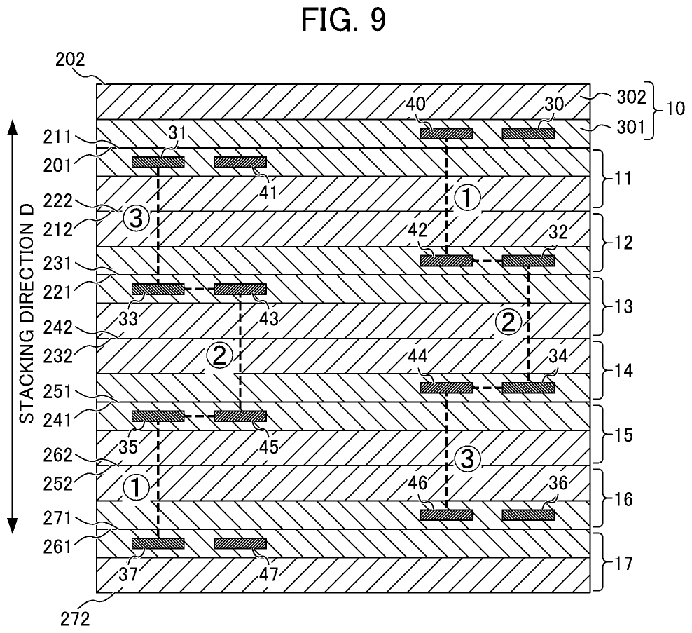

Next, a semiconductor device 1 and a method for manufacturing the semiconductor device 1 according to a third embodiment of the present invention will be described with reference to FIGS. 8 and 9. In description of the third embodiment, the same reference numerals are used to represent the same elements as those of the above-described embodiments, and description thereof will be omitted or simplified. The semiconductor device 1 according to the third embodiment is different from those of the first and second embodiments in that a transmission coil 30 is, in a stacking direction D, adjacent to a reception coil 42 of another chip 12 with at least one still another chip 11 interposed therebetween. The semiconductor device 1 according to the third embodiment is different from those of the first and second embodiments in the following points: four channels are provided as shown in FIG. 8, and after a front surface 211 of one substrate 21 (a chip 11) and a front surface 201 of another substrate 20 (a chip 10) have been bonded to each other with intersections thereof aligned with each other, a bonded body of the chips 10, 11 is stacked on another bonded body of chips 12, 13 such that back surfaces 212, 222 are adjacent to each other in a state in which the bonded body of the chips 10, 11 is rotated 180 degrees about an axis connecting the intersections C with respect to another bonded body of the chips 12, 13. The semiconductor device 1 in the second embodiment is different from those of the first and second embodiments in that the transmission coil 30 and a reception coil 40 are arranged at positions opposing each other with respect to the intersection and the transmission coil 30 and the reception coil 40 are not line-symmetrical to each other with respect to any of reference axes A2, A3, but are point-symmetrical to each other. Thus, the semiconductor device 1 according to the third embodiment is different from those of the first and second embodiments in that communication is made between the odd-numbered chip 10, 12, . . . and the even-numbered chip 11, 13, . . . as shown in FIG. 9.

According to the semiconductor device 1 and the method for manufacturing the semiconductor device 1 according to the first embodiment as described above, the following advantageous effects are produced.

(11) The transmission coil 30 is, in the stacking direction D, adjacent to the reception coil 42 of another chip 12 with at least one still another chip 11 interposed therebetween With this configuration, the number of transmission paths (the number of stages) can be reduced, and therefore, latency can be reduced.

Each of the preferred embodiments of the semiconductor device and the method for manufacturing the semiconductor device according to the present invention has been described above, but the present invention is not limited to the above-described embodiments and changes can be made as necessary.

For example, in the above-described embodiments, three or four channels are provided, but the number of channels is not limited to above. It may only be required that one or more channels are provided.

In the third embodiment, the transmission coil 30 and the reception coil 42 are adjacent to each other in the stacking direction D with one chip 11 interposed therebetween, but the present invention is not limited to above. The transmission coil 30, 31, . . . and the reception coil 40, 41, . . . may be adjacent to each other with two or more chips interposed therebetween.

In the above-described embodiments, eight chips 10, 11, 12, are stacked on each other, but the present invention is not limited to above. It may only be required that the semiconductor device 1 is configured such that three or more chips are stacked on each other.

### EXPLANATION OF REFERENCE NUMERALS

1 Semiconductor Device
10, 11, . . . , 17 Chip
20, 21, . . . , 27 Substrate
30, 31, . . . , 37 Transmission Coil
40, 41, . . . , 47 Reception Coil
50, 51, . . . , 57 Transmission Circuit
60, 61, . . . , 67 Transmission-Side Driver
70, 71, . . . , 77 Reception Circuit
80, 81, . . . , 87 Reception-Side Receiver
201, 211, . . . , 271 Front Surface
202, 212, . . . , 272 Back Surface
A1, A2, A2 Reference Axis
C Intersection
D Stacking Direction

1. A semiconductor device comprising: three or more chips stacked on each other,
wherein each of the chips includes
a substrate,
a transmission coil, and
a reception coil provided in a region where the reception coil does not overlap with the transmission coil in an in-plane direction of the substrate,
the transmission coil is arranged in a region where the transmission coil is adjacent to and overlaps with the reception coil of another chip in a stacking direction, and
the reception coil is configured such that data is transmittable between the reception coil and the transmission coil arranged on the same substrate.

2. The semiconductor device according to claim 1, wherein two or more pairs of the reception coil and the transmission coil are provided.

3. The semiconductor device according to claim 1, wherein the transmission coil is provided at a predetermined position on the substrate at a position opposing the reception coil with respect to a reference axis extending along the in-plane direction

4. The semiconductor device according to claim 3, wherein the substrate includes
a front surface as one surface in a thickness direction, and
a back surface as the other surface in the thickness direction,
the front surface is stacked adjacent to the front surface of the substrate of another chip, and
the back surface is stacked adjacent to the back surface of the substrate of still another chip.

5. The semiconductor device according to claim 1, wherein the transmission coil is, on the substrate, provided at a predetermined position opposing the reception coil with respect to an intersection between two reference axes extending in the in-plane direction and extending perpendicular to each other.

6. The semiconductor device according to claim 5, wherein the substrate includes
a front surface as one surface in a thickness direction, and
a back surface as the other surface in the thickness direction,
the front surface is stacked adjacent to the back surface of the substrate of another chip, and
the back surface is stacked adjacent to the front surface of the substrate of still another chip.

7. The semiconductor device according to claim 4, wherein the transmission coil is, in the stacking direction, adjacent to the reception coil of another chip with at least one still another chip interposed therebetween.

8. The semiconductor device according to claim 1, wherein the chip includes
a transmission circuit connected to the transmission coil to transmit transmission data to the transmission coil,
a reception circuit connected to the reception coil to receive reception data from the reception coil,
a transmission-side driver that switches connection between the transmission coil and the transmission circuit, and
a reception-side receiver that switches connection between the reception coil and the reception circuit

9. The semiconductor device according to claim 8, wherein the transmission-side driver switches the connection between the transmission coil and the transmission circuit based on a transmission direction of the transmission data along the stacking direction, and
the reception-side receiver switches the connection between the reception coil and the reception circuit according to switching by the transmission-side driver.

10. The semiconductor device according to claim 1, wherein the transmission coil is different from the reception coil in at least any one of the number of turns, a wire width, an inter-wire space, or a wire to be used.

11. A method for manufacturing the semiconductor device according to claim 1, the semiconductor device being manufactured in such a manner that wafers are stacked on each other and are subsequently divided into pieces.

12. The semiconductor device according to claim 5, wherein the transmission coil is, in the stacking direction, adjacent to the reception coil of another chip with at least one still another chip interposed therebetween.
